(19) United States
(12) Patent Application Publication
(10) Pub. No.: US 2012/0081616 A1
(43) Pub. Date: Apr. 5, 2012

(54) LIGHT EMITTING DIODE MODULE, FLAT PANEL MONITOR HAVING THE LIGHT EMITTING DIODE MODULE, AND METHOD OF OPERATING THE SAME

(75) Inventor: Hsin-Chieh HUANG, Hsinchu City (TW)

(73) Assignee: TAIWAN SEMICONDUCTOR MANUFACTURING COMPANY, LTD., Hsinchu (TW)

(21) Appl. No.: 12/898,082

(22) Filed: Oct. 5, 2010

(51) Int. Cl. H04N 5/66; G09G 3/32; G09G 5/10; H01L 33/58; H05B 37/02

(52) U.S. Cl. 348/739; 257/88; 315/312; 315/152; 345/690; 257/E33.067; 345/82; 348/E05.133

(57) ABSTRACT

The present application describes a light emitting diode (LED) bar comprising a substrate, a plurality of LED modules, a detector, and a LED driver. The plurality of LED modules are positioned over the substrate, and each LED module has a lens and at least two substantially identical LED units covered by the lens. The detector is positioned on the substrate and configured to detect an operating status of at least one of the LED modules. The LED driver is positioned on the substrate and configured to drive the at least one of the LED modules based on the detected operating status.

### BACKGROUND

Light emitting diodes (LEDs) are being used in a wide range of applications including indicator lamps, displays, and backlighting for liquid crystal displays (LCDs). Other uses of LEDs include providing external vehicular lighting or outdoor lighting such as street lamps and traffic lights. LED devices have become more popular because they have longer lifetime and use less electricity than traditional incandescent bulbs.

An LED emits light when a voltage is applied across a p-n junction of oppositely doped semiconductor layers. Different wavelengths of light can be generated by varying the band-gaps of the semiconductor layers and/or by forming an active layer between the oppositely doped semiconductor layers. Usually, the applied electrical current controls the intensity of the light emitted by the LED. Additionally, a phosphor material can be coated on the LED to change the properties of light emitted by the LED.

### DESCRIPTION OF THE DRAWINGS

One or more embodiments are illustrated by way of example, and not by limitation, in the figures of the accompanying drawings, wherein elements having the same reference numeral designations represent like elements throughout and wherein:

FIGS. 1A and 1B are perspective views of a flat panel monitor;

FIG. 2 is a side view of an LED light bar according to some embodiments;

FIG. 3 is a cross sectional view of an LED module according to an embodiment;

FIG. 4A is a functional block diagram of an LED light bar according to some embodiments;

FIG. 4B is a top view of the LED light bar according to an embodiment implementing the configuration depicted in FIG. 4A;

FIG. 5A is a functional block diagram of another LED light bar according to some embodiments;

FIG. 5B is a top view of the LED light bar according to an embodiment implementing the configuration depicted in FIG. 5A; and

FIG. 6 is a flowchart of a method for operating an LED module according to an embodiment.

### DETAILED DESCRIPTION

It is understood that the following disclosure provides many different embodiments, or examples, for implementing different features of various embodiments of this invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Although an LED has a longer lifetime than a traditional light bulb, the LED still has a limited life span. There are many factors that cause the degradation or even failure of an LED, and thus affect the lifetime of the LED. For example, one of the factors is that, when using an LED as a light source, a portion of the input power is converted to heat. Over time, as the LED is subjected to repeated intervals of use, the repeated heating and cooling causes degradation of the semiconductor materials of the LED. As a result of this degradation, the intensity of the light emitted by the LED in response to a given current drops, and a larger current is required to cause the LED to maintain the same light intensity. Receipt of a larger driving current in turn accelerates the process of degradation. Eventually, the LED generates no perceptible light regardless of the amount of current applied to the LED. Under some circumstances, the degradation further causes the LED to fail completely, and the LED ceases to function. In some configurations, the LED has the characteristics of an open circuit or a short circuit when the LED fails.

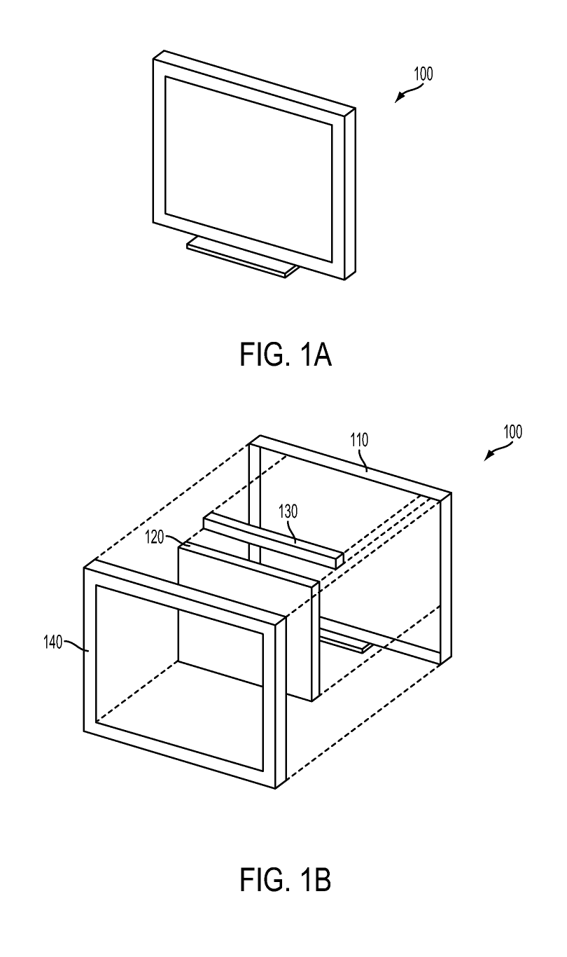

FIG. 1A is a perspective view of a flat panel monitor 100, such as a LCD monitor or a flat panel TV. FIG. 1B is an exploded view of the flat panel monitor 100. The flat panel monitor 100 has a casing 110, a display panel 120, an LED light bar 130, and a front bezel 140. The front bezel 140 and the casing 110 form a housing for receiving the display panel 120 and the LED light bar 130. The display panel 120 displays an image to a user and the LED light bar 130 provides backlight for the display panel 120. In some embodiments, the flat panel monitor 100 further includes a television tuner (not shown) that is coupled to the display panel 120 and converts an RF signal into an image for display.

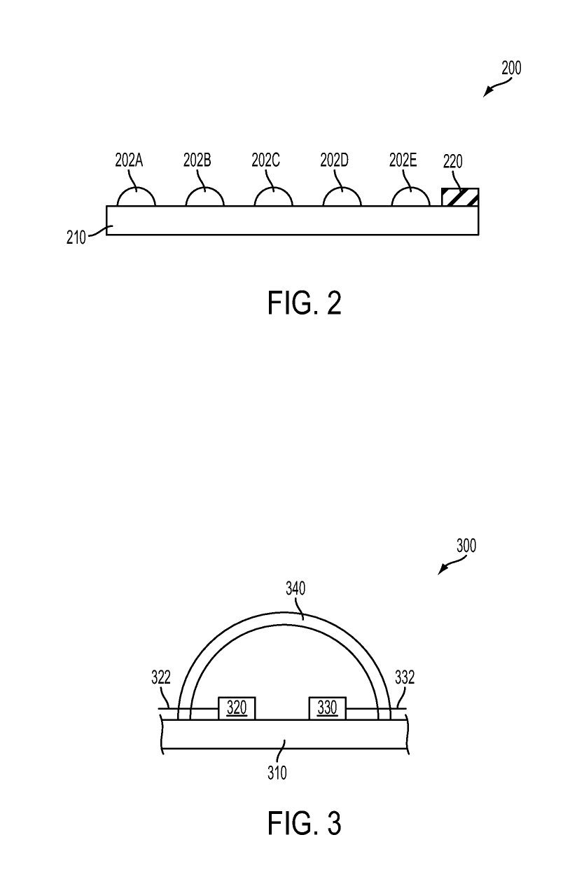

FIG. 2 is a side view of an LED light bar 200 according to some embodiments. The LED light bar 200 has a plurality of LED modules 202a-202e mounted on a substrate 210. The LED light bar 200 also has a control circuit 220 mounted on the substrate 210 for controlling the operation of the plurality of LED modules 202a-202e. Although five LED modules are mounted on the substrate in FIG. 2, in some embodiments, there are more or less than five LED modules 202a-202e on the substrate 210.

For an electrical device that includes LEDs, such as the flat panel monitor 100 that relies on the LED light bar 130 to provide backlighting, failure of one or more LEDs renders the entire device useless.

One way to repair the failed LEDs is to take the electrical device off-line and replace the damaged LEDs with new ones. For example, to replace a failed LED that provides backlighting for a flat panel monitor 100, a technician turns off the flat panel monitor 100, disassembles the flat panel monitor 100, and replace the entire backlighting unit (such as the LED light bar 130 or other similar LED backlighting devices) having the damaged LED. Similarly, repairing a traffic light containing failed LEDs requires taking the traffic light offline and replacing the damaged LEDs with new ones. Such replacement of damaged LEDs with new ones incurs significant downtime and is inconvenient, time-consuming, and costly.

FIG. 3 is a cross sectional view of an LED module 300 according to an embodiment. The LED module 300 is usable in the LED light bar as depicted in FIG. 2 or other similar applications. The LED module 300 has a substrate 310, a first LED unit 320, a second LED unit 330, and a lens 340. The first LED unit 320 and the second LED unit 330 are positioned in a side-by-side arrangement over the substrate 310. The distance between the first LED unit 320 and the second LED unit 330 varies depending on the size of the lens 340.

The lens 340 is positioned over the substrate and encloses first LED unit 320 and the second LED unit 330. The lens 340 is made of a material that allows transmission of a light emitted from the first LED unit 320 or the second LED unit 330 through the lens 340. In some embodiments, the lens 340 is a dome-shaped lens. In addition, the LED module 300 has a first signal path 322 coupled to the first LED unit 320 and a second signal path 332 coupled to the second LED unit 330, that both extend out of the disclosure, for controlling the first LED unit 320 and the second LED unit 330. The first LED unit 320 and the second LED unit 330 are controlled separately through the first signal path 322 and the second signal path 332.

In the present embodiment, the first LED unit 320 and the second LED unit 330 are substantially identical. In some embodiments, the first LED unit 320 and the second LED unit 330 are LED chips formed on the same wafer concurrently and subsequently dissected into separate LED chips. In yet some further embodiments, the first LED unit 320 and the second LED unit 330 are LED units formed on an undivided LED substrate.

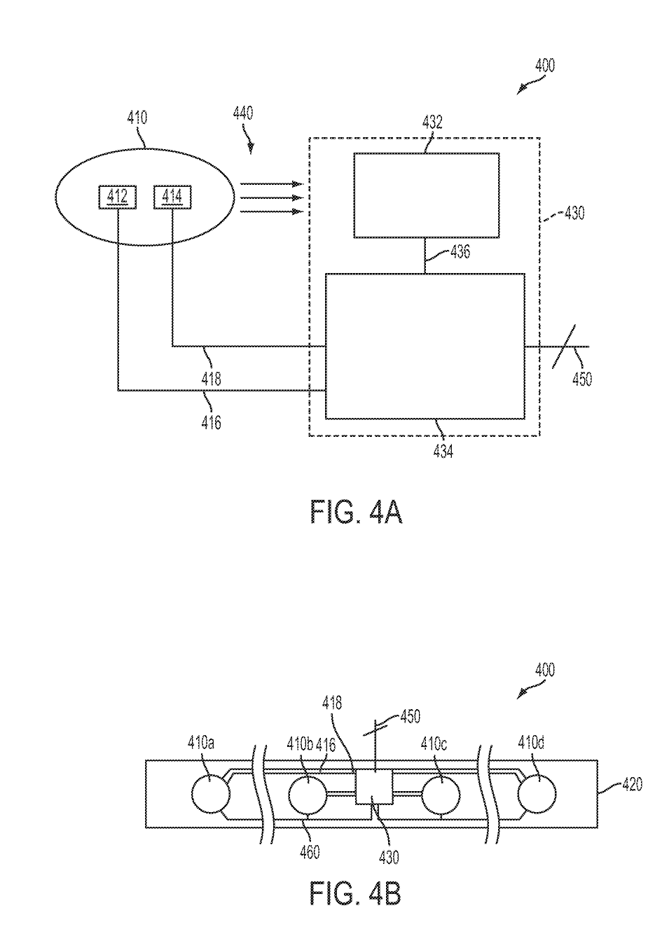

FIG. 4A is a functional block diagram of an LED light bar 400 according to some embodiments. An LED module 410 is mounted on a substrate (420 in FIG. 4B) and has a first LED unit 412 and a second LED unit 414 that are separately controlled by a control circuit 430. The control circuit 430 has a driver 434 that drives the first LED unit 412 and the second LED unit 414 through a first LED control signal path 416 and a second LED control signal path 418. In some embodiments, there are more than two LED units in the LED module 410. Although only one LED module 410 is depicted in FIG. 4A, in some embodiments, the LED light bar 400 has more than one LED modules (such as LED modules 410a-410d in FIG. 4B).

The driver 434 is communicatively and/or electrically coupled to the detector 432 in order to receive an operating status of the LED module 410 by a detector signal path 436. The operating status refers to light intensity of a light 440 emitted by the LED module 410. Light intensity is normally defined as power of the emitted light per unit area. The detector 430 senses the light power applied to the detector 430 and converts the received light power into electrical signals as representative values of the light intensity. Based on the detected light intensity, the driver 434 determines the amounts of driving current for the first LED unit 412 and the second LED unit 414 in order to maintain the detected light intensity of the light 470 at a predetermined level of intensity. The driver 434 controls the driving current fed to the first LED unit 412 and the second LED unit 414.

In some embodiments, the LED units 412 and 414 are not turned on concurrently. For example, initially only the first LED unit 412 is turned on in the LED module 410. Subsequently, the driver turns off the first LED unit 412 and turns on the second LED 414 when the detected light intensity of the LED module 410 is not within a predetermined range, i.e., the light intensity emitted by the first LED unit 412 is outside the range.

In some other embodiments, when light emitted by only the first LED unit 412 or the second LED unit 414 is outside the predetermined range, both the first LED unit 412 and the second LED unit 414 are turned on.

In some embodiments, the LED driver 434 comprises a storage device for retaining the value(s) for the predetermined level of intensity or the predetermined range of light intensity. In some other embodiments, the value(s) of predetermined level of intensity or the predetermined range of light intensity are transmitted to the LED driver 434 via a plurality of LED light bar control paths 450 coupled to the control circuit 430.

FIG. 4B is a top view of the LED light bar according to an embodiment implementing the configuration depicted in FIG. 4A. The LED light bar 400 has a substrate 420 on which the LED modules are mounted. The control circuit 430 is mounted on the substrate 420, as well. Each LED module 410a-410d is coupled to the control circuit 430 through at least two signal paths 416/418 allowing the control circuit 430 to separately control LED units of each LED module 410a-410d. A person of ordinary skill in the art will appreciate that, in some embodiments, there are more or less than four LED modules in a LED light bar. In at least one embodiment, there is only one LED module in an LED light bar.

The detector 432 is a photo detector that detects intensity of a light emitted by the LED module 410, or one or more LED modules 410a-410d in FIG. 4B. In some embodiments, the photo detector is a charge-coupled device or a complementary metal-oxide-semiconductor (CMOS) detector. In other embodiments, the photo detector is a simple photovoltaic cell such as a solar cell or another LED.

The LED light bar 400 further has a plurality of waveguides 460 that couple at least a portion of the light emitted by the LED modules 410a-410d to the detector 432. Each of the waveguides 460 has an end positioned adjacent to a corresponding one of the LED modules 410a-410d. In some embodiments, instead of having one detector 432 coupled with a plurality of waveguides 460, the LED light bar 400 has a plurality of detectors each positioned adjacent to corresponding LED modules 410a-410d, and the waveguides are omitted. The detection results are transmitted to the driver 434 through one or more signal paths, e.g., one or more detector signal paths 436.

The waveguides 460 and/or the detector 432 are positioned so that only the light generated at a particular LED module is detected at a time without capturing interfering light from other LED modules or reflected light. In some embodiments, the waveguides 460 are optic fibers, light pipes, covered trenches in the substrate 420, or other waveguides able to transfer or direct photons. The detector 432 is capable of detecting various light properties, such as intensity, color, color temperature, or spectral distribution.

The LED modules 410a-410d are similarly controlled by the control circuit 430. In some embodiments, on top of the LED modules 410a-410d controlled by the detector 432 and the driver 434, at least one additional LED module positioned on the substrate 420 and only coupled to the driver 434. The at least one additional LED module is driven without any feedback control based on detection of the operating status.

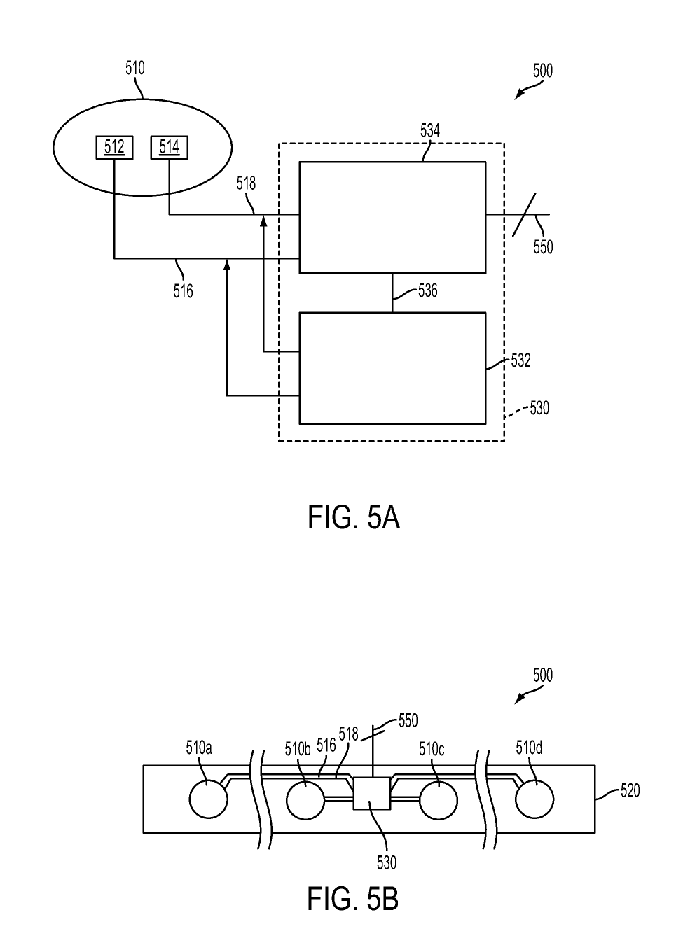

FIG. 5A is a functional block diagram of another LED light bar 500 according to some embodiments. An LED module 510 is mounted on a substrate (520 in FIG. 5B) and has a first LED unit 512 and a second LED unit 514 that are separately controlled by a control circuit 530. The control circuit 530 has a driver 534 that drives the first LED unit 512 and the second LED unit 514 through a first LED control signal path 516 and a second LED control signal path 518. In some embodiments, there are more than two LED units in the LED module 510. Although only one LED module 510 is depicted in FIG. 5A, in some embodiments the LED light bar 500 has more than one LED module (such as LED modules 510a-510d in FIG. 5B).

Normally, a failed LED unit or a failed LED chip has characteristics of an open circuit or a short circuit. As such, the detector 532 is an open circuit detector and/or a short circuit detector that detects if the LED units 512 or 514 of the LED module 510a have a characteristic of an open circuit or a short circuit. In some embodiments, the detector 532 is a current sensor that detects if a driving current of the LED units 512 and 514 of the LED module 510 is outside a predetermined range, such as having no current at all or having an excessive amount of current. In some embodiments, the detector 532 is an Ohm sensor that detects if turned-on resistances of the LED units 512 and 514 of the LED module 510 are outside a predetermined range, such as having zero resistance or an excessive level of resistance.

The driver 534 is coupled to the detector 532 by a signal path 536 in order to receive an operating status of the LED module 510. The operating status refers to whether the LED units 512 and 514 have failed. The driver 534 controls the driving current fed to the first LED unit 512 and the second LED unit 514. In at least one embodiment, the LED units 512 and 514 are not turned on concurrently. For example, initially only the first LED unit 512 is turned on in the LED module 510. Subsequently, the driver turns off the first LED unit 512 and turns on the second LED 514 after determining failure of the first LED 512 unit.

In some embodiments, the LED driver 534 comprises a storage device for retaining the information of whether a LED unit has failed. In some other embodiments, the information of failed LED units is transmitted to the LED driver 534 via a plurality of LED light bar control paths 550 are coupled to the control circuit 530.

FIG. 5B is a top view of the LED light bar according to an embodiment implementing the configuration depicted in FIG. 5A. Similar to the LED light bar depicted in FIG. 4B, the LED light bar 500 depicted in FIG. 5B has one or more LED modules 510a-510d similar to the embodiment depicted in FIG. 3. The LED light bar 500 further has a substrate 520 and a control circuit 530. The LED modules 510a-510d and the control circuit 530 are mounted on the substrate 520. Each LED module 510a-510d is coupled to the control circuit 530 through at least two signal paths 540 for allowing the control circuit 530 to control LED units of each LED module separately.

The LED modules 510b-510d are similarly controlled by the control circuit 530. In some embodiments, on top of the LED modules 510a-510d controlled by the detector 532 and the driver 534, at least one additional LED module positioned on the substrate 520 and only coupled to the driver 534. The at least one additional LED module is driven without any feedback control based on detection of the operating status.

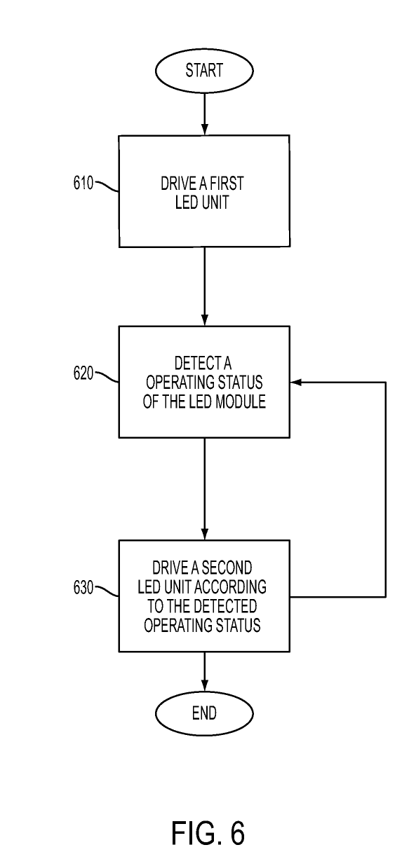

FIG. 6 is a flowchart of a method of operating an LED module according to an embodiment. In some embodiments, additional operations are performed before, during, and/or after the method of FIG. 6.

In operation 610, the control circuit 430 or 530 drives a first LED unit 412 or 512 of the LED module 410 or 510, i.e., the driver 434 or 534 supplies a driving current to the first LED unit 412 or 512. As a result, the first LED unit 412 or 512 emits a light. At this stage, no current is supplied to the second LED unit 414 or 514.

Subsequently, in operation 620 the control circuit 430 or 530 detects an operating status of the LED module 410a or 510a. In the embodiments depicted in FIG. 4A, the operating status refers to light intensity of a light emitted by the LED module 410 or if any one of the LED units 412 or 414 has failed based on the detected light intensity. In the embodiment depicted in FIG. 5A, the operating status refers to whether any one of the LED units 512 or 514 failed based on a showing of a characteristic of an open circuit or a short circuit when the LED unit is driven to be turned on.

In operation 630, the control circuit 430 or 530 drives the second LED unit 414 or 514 of the LED module 410 or 510 according to the detected operating status. In at least one embodiment as depicted in FIG. 4A, the control circuit drives the second LED unit 414 for maintaining a light intensity level of the LED module 410 equal to a predetermined intensity level. In another embodiment as depicted in FIG. 4A, the control circuit 430 or 530 turns on the second LED unit 414 and further turns off the first LED unit 412 when the detected light intensity is not within (outside) a predetermined range. In the embodiment depicted in FIG. 5A, the control circuit turns on the second LED unit 514 and further turns off the first LED unit 512 after determining that the first LED unit 512 is failed, i.e., has a characteristics of an open circuit or a short circuit.

In some embodiments, operations 620 and 630 are performed in a cyclical manner until the entire LED module is turned off. The frequency for detecting the operating status is dependent on the application and/or the type of LED device being used.

In at least one embodiment, the methods described above are performed for calibrating an LED light bar, such as in response to a calibration button of the flat panel monitor being pressed. When calibrating, the method repeats operation 620 and operation 630 until the operating status indicates that there is no need to further adjust LEDs. In some embodiments, the feedback control is implemented with simple logic that merely increases or decreases the driver output incrementally until a desired light output is detected.

In some embodiments, the control circuit of the LED module or the LED light bar includes a memory that allows the control circuit to compare the detected operating status with a historical value, such as an initial light intensity. The ability to save an initial light intensity or other historical value in the memory is useful for each LED to be calibrated or normalized. In some embodiments, if LEDs with similar characteristics are binned before they are grouped into the same device, the LEDs share a single initial light intensity. In yet some other embodiments, the LEDs may be tested to determine an initial light intensity.

Certain embodiments in accordance with the present disclosure are usable in flat panel monitors containing direct-type LED backlighting. In flat panel monitors with direct-type LED backlights, the LEDs are distributed on a plate behind the display panel. When a flat panel monitor is turned on, the LEDs on that display panel create backlighting and the backlight is visible from the front of the LCD panel. Other embodiments in accordance with the present disclosure are usable in flat panel monitors containing edge-type LED backlighting (such as the configuration depicted in FIG. 1B). Unlike panels with direct-type LED backlighting (in which LEDs are placed on a panel behind the display panel), in display panels with edge-type LED backlighting, the LEDs are placed on one or more elongated bars that are positioned on the edges of the display panel.

If, during the operation of a flat panel monitor according to the present disclosure, a first LED unit in an LED module fails, the user is not required to turn off the flat panel monitor and go through the process of identifying and replacing the defective LED(s). Instead, if the first LED unit generates insufficient light output, the control circuit is able to provide uninterrupted illumination by driving a second LED unit in the LED module. When the second LED unit comes online, the first LED unit may be turned off allowing the second LED unit to be used as the light source. Or, as discussed above, the first LED unit may remain turned on even after the second LED unit is turned on.

The foregoing has outlined features of several embodiments so that those skilled in the art may better understand the detailed description that follows. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions and alterations herein without departing from the spirit and scope of the present disclosure.

What is claimed is:

1. A light emitting diode (LED) module comprising:
a substrate;
a lens positioned over the substrate, the lens and the substrate defining an enclosure;
a first LED unit positioned over the substrate within the enclosure;
a second LED unit positioned over the substrate within the enclosure;
a first signal path coupled to the first LED unit and extending out of the enclosure; and
a second signal path coupled to the second LED unit and extending out of the enclosure;
wherein the second LED unit is configured to be turned on in respond to a failure of the first LED.

2. The LED module of claim 1, wherein the first LED unit and the second LED unit are substantially identical.

3. The LED module of claim 1, wherein the first LED unit and the second LED unit are formed on an undivided LED substrate.

4. A light emitting diode (LED) light bar comprising:
a substrate;
a plurality of LED modules positioned over the substrate, each LED module comprising a lens and at least two substantially identical LED units covered by the lens;
a detector configured to detect an operating status of at least one of the LED modules; and
an LED driver positioned on the substrate and configured to turn on only one of the LED units of the at least one of the LED modules at a time based on the detected operating status.

5. The LED light bar of claim 4, wherein the detector is a photo detector, and the operating status comprises light intensity of a light emitted by at least one of the LED modules.

6. The LED light bar of claim 5, further comprising a waveguide coupled to the photo detector and the plurality of LED modules, the waveguide being configured to direct a portion of the light to the photo detector.

7. The LED light bar of claim 5, wherein the detector is positioned adjacent to the plurality of LED modules.

8. The LED light bar of claim 5, wherein the LED driver is configured to drive the at least two LED units for maintaining the detected light intensity at a predetermined level of intensity.

9. The LED light bar of claim 5, wherein the LED driver is configured to turn off one of the LED units and turn on another one of the LED units when the detected light intensity is not within a predetermined range.

10. The LED light bar of claim 4, wherein the detector is configured to determine if one of the LED units has a characteristic of an open circuit or a short circuit when the one of the LED units is driven to be turned on.

11. The LED light bar of claim 10, wherein the LED driver is configured to turn off the one of the LED units and turn on another one of the LED units when the one of the LED units is determined to have the characteristic of an open circuit or a short circuit.

12. A flat panel monitor comprising:
a display panel;
a light emitting diode (LED) light bar configured to light the display panel, the LED light bar comprising:
a substrate;
a plurality of LED modules positioned over the substrate, each LED module comprising a lens and at least two substantially identical LED units covered by the lens;
a detector positioned on the substrate and configured to detect an operating status of at least one of the LED modules; and
an LED driver positioned on the substrate and configured to turn on only one of the LED units of the at least one of the LED modules at a time based on the detected operating status.

13. The flat panel monitor of claim 12, wherein the flat panel monitor is a television.

14. The flat panel monitor of claim 12, wherein the detector is a photo detector, and the operating status comprises light intensity of a light emitted by at least one of the LED modules.

15. The flat panel monitor of claim 14, further comprising a waveguide coupled to the photo detector and the plurality of LED modules, the waveguide being configured to direct a portion of the light to the photo detector.

16. The flat panel monitor of claim 14, wherein the detector is positioned adjacent to the plurality of LED modules.

17. The flat panel monitor of claim 14, wherein the LED driver is configured to drive the at least two LED units for maintaining the detected light intensity at a predetermined level of intensity.

18. The flat panel monitor of claim 14, wherein the LED driver is configured to turn off one of the LED units and turn on another one of the LED units when the detected light intensity is not within a predetermined range.

19. The flat panel monitor of claim 12, wherein the detector is configured to determine if one of the LED units has a characteristic of an open circuit or a short circuit when the one of the LED units is driven to be turned on.

20. The flat panel monitor of claim 19, wherein the LED driver is configured to turn off the one of the LED units and turn on another one of the LED units when the one of the LED units is determined to have the characteristic of an open circuit or a short circuit.
